(19) United States
(12) Patent Application Publication
(10) Pub. No.: US 2018/0219055 A1
(43) Pub. Date: Aug. 2, 2018

(54) FLEXIBLE VERTICAL CHANNEL ORGANIC THIN FILM TRANSISTOR AND MANUFACTURE METHOD THEREOF

(71) Applicant: Wuhan China Star Optoelectronics Technology Co., Ltd., Wuhan City (CN)

(72) Inventors: Chenghao Bu, Wuhan City (CN); Guoren Hu, Wuhan City (CN)

(21) Appl. No.: 15/506,239

(22) PCT Filed: Dec. 29, 2016
(86) PCT No.: PCT/CN2016/113013

§ 371 Date: Feb. 24, 2017

(30) Foreign Application Priority Data
Dec. 9, 2016 (CN) 201611129977.9

(51) Int. Cl. H01L 27/32; H01L 51/10; H01L 51/05; H01L 51/52

(52) U.S. Cl. CPC H01L 27/3274; H01L 51/102; H01L 51/0558; H01L 51/0048; H01L 51/057; H01L 51/5206; H01L 27/3262; H01L 51/0525

(57) ABSTRACT

Provided is a flexible vertical channel organic thin film transistor and a manufacture method thereof, which change the traditional configuration of the horizontal channel organic TFT and use the vertical channel configuration to tremendously shorten the channel length so that the TFT can obtain the larger source-drain current under the lower drive voltage; by using the flawless, high conductive and high transparent graphene material to manufacture the gate, the electronic performance of the TFT can be better; by using the hexagonal boron nitride material to manufacture the gate insulation layer to interact with the gate made by graphene, the electronic performance of the TFT can be promoted; because both the graphene and the hexagonal boron nitride materials are two dimension atomic layer structure material with better bendability and the channel layer uses the flexible organic semiconductor layer, the bendability of the entire TFT can be significantly promoted.

### FIELD OF THE INVENTION

The present invention relates to a display technology field, and more particularly to a flexible vertical channel organic thin film transistor and a manufacture method thereof.

### BACKGROUND OF THE INVENTION

With the development of display technology, the flat panel device, such as Liquid Crystal Display (LCD) possesses advantages of high image quality, power saving, thin body and wide application scope. Thus, it has been widely applied in various consumer electrical products, such as mobile phone, television, personal digital assistant, digital camera, notebook, laptop, and becomes the major display device.

The Organic Light Emitting Display (OLED) display, which is also named as Organic electroluminescent display, is a new flat panel display device. Because it possesses many outstanding properties of self-illumination, low driving voltage, high luminescence efficiency, short response time, high clarity and contrast, near 180° view angle, wide range of working temperature, applicability of flexible display and large scale full color display. The OLED is considered as the most potential display device in the industry.

In comparison with the LCD display, the OLED display panel has advantages such as higher brightness, wider view angle, faster response speed, larger contrast and lighter weight, and has been drawn more attentions in the display market now. The OLED display is a current drive element, and thus has the higher requirement proposed for the backplate technology containing the active array. At present, most of the small size OLED display uses the thin film transistor array (TFT array) in which the low temperature polysilicon is used for the active layer. However, the LTPS backplate technology increases the process time, the energy consumption and the cost. Meanwhile, a large amount of crystal boundaries exist in the polysilicon. The manufacture technology has difficulty to ensure obtaining the uniform large area thin film. All these will influence the electronic parameters of the TFT element, such as the threshold voltage and the leak current. Then, the pixel driven thereby shows the issue of unstable illumination. For stabilizing the threshold voltage of the LTPS-TFT, the panel makers generally design the 7T1C pixel compensation circuit even it reduces the pixel aperture ratio of the OLED element, and influences the illumination performance. In the meantime, the manufacture process is more complicated. Besides, the low temperature polysilicon is the inorganic semiconductor material, and the Young's modulus is larger, which counts against the manufacture of the flexible TFT backplate in the flexible OLED display. The manufacture of the organic thin film transistor (OTFT) is simple, and easy to be bent, and is suitable for manufacturing the flexible OLED display. However, the carrier mobility is lower, and for obtaining the current capable of driving the OLED pixel, it is required to shorten the channel length as possible in the traditional horizontal structure OTFT but it needs the high resolution exposure technology, and enormously increase the exposure cost. The American nVerpix company proposed an organic thin film transistor element on the basis of the vertical channel structure to obtain the higher on state current and the lower drive voltage. However, the used gate material and the gate insulation material make the element hard to be truly bent and restrict the application of the vertical channel structure OTFT in the flexible OLED display.

### SUMMARY OF THE INVENTION

An objective of the present invention is to provide a manufacture method of a flexible vertical channel organic thin film transistor, and the manufactured flexible vertical channel organic thin film transistor has a shorter channel length to obtain the larger source drain current under the lower drive voltage, and it is beneficial for driving the OLED pixel to emit light under low voltage and meanwhile, it possesses the better bendability.

Another objective of the present invention is to provide a flexible vertical channel organic thin film transistor with a shorter channel length to obtain the larger source drain current under the lower drive voltage, and it is beneficial for driving the OLED pixel to emit light under low voltage and meanwhile, it possesses the better bendability.

For realizing the aforesaid objectives, the present invention provides a manufacture method of a flexible vertical channel organic thin film transistor, comprising steps of:

step 1, providing a rigid substrate, and forming a flexible substrate on the rigid substrate, and forming a gate on the flexible substrate;

step 2, forming a gate insulation layer on the gate, and a dimension of the gate insulation layer is smaller than a dimension of the gate;

forming a source on the gate insulation layer, and a dimension of the source is smaller than or equal to the dimension of the gate insulation layer;

step 3, forming an organic semiconductor layer on the source, and a dimension of the organic semiconductor layer is smaller than the dimension of the source;

forming a drain on the organic semiconductor layer, and a dimension of the drain is smaller than or equal to the dimension of the organic semiconductor layer;

forming a source contact electrode which is separately located with the organic semiconductor layer on the source;

forming a gate contact electrode which is separately located with the gate insulation layer on the gate;

step 4, stripping the flexible substrate from the rigid substrate to obtain the flexible vertical channel organic thin film transistor.

A material of the gate is graphene; a material of the gate insulation layer is hexagonal boron nitride.

A material of the source is carbon nano-tube; a material of the organic semiconductor layer is P type organic semiconductor material; a thickness of the organic semiconductor layer is 80 nm-120 nm.

In step 3, one mask is employed with an evaporation method to form the drain, the source contact electrode and the gate contact electrode, and materials of the drain, the source contact electrode and the gate contact electrode are the same; the materials of the drain, the source contact electrode and the gate contact electrode are metal.

Step 3 further comprises a step of manufacturing an OLED display unit on the organic semiconductor layer and the drain, and the OLED display unit comprises a Hole Injection layer, an organic light emitting layer, an Electron Injection layer and the cathode which are sequentially stacked up on the organic semiconductor layer and the drain from bottom to top, and the drain serves as an OLED anode.

The present invention further provides a flexible vertical channel organic thin film transistor, comprising: a flexible substrate, a gate located on the flexible substrate, a gate insulation layer and a gate contact electrode which are located on the gate and separately located, a source located on the gate insulation layer, an organic semiconductor layer and a source contact electrode which are located on the source and separately located and a drain located on the organic semiconductor layer.

A material of the gate is graphene; a material of the gate insulation layer is hexagonal boron nitride.

A material of the source is carbon nano-tube; a material of the organic semiconductor layer is P type organic semiconductor material; a thickness of the organic semiconductor layer is 80 nm-120 nm.

The drain, the source contact electrode and the gate contact electrode are formed in the same evaporation process, and thus materials are the same; the materials of the drain, the source contact electrode and the gate contact electrode are metal.

The flexible vertical channel organic thin film transistor further comprise an OLED display unit located on the organic semiconductor layer and the drain, and the OLED display unit comprises a Hole Injection layer, an organic light emitting layer, an Electron Injection layer and the cathode which are sequentially stacked up on the organic semiconductor layer and the drain from bottom to top, and the drain serves as an OLED anode.

The present invention further provides a flexible vertical channel organic thin film transistor, comprising: a flexible substrate, a gate located on the flexible substrate, a gate insulation layer and a gate contact electrode which are located on the gate and separately located, a source located on the gate insulation layer, an organic semiconductor layer and a source contact electrode which are located on the source and separately located and a drain located on the organic semiconductor layer;

wherein a material of the gate is graphene; a material of the gate insulation layer is hexagonal boron nitride;

wherein a material of the source is carbon nano-tube; a material of the organic semiconductor layer is P type organic semiconductor material; a thickness of the organic semiconductor layer is 80 nm-120 nm.

The benefits of the present invention are: the present invention provides a flexible vertical channel organic thin film transistor and a manufacture method thereof, which change the traditional configuration of the horizontal channel organic thin film transistor and use the vertical channel configuration to tremendously shorten the channel length so that the thin film transistor can obtain the larger source-drain current under the lower drive voltage, which is beneficial for driving the OLED pixel to emit light under low voltage, the high resolution exposure technology is not required to save the production cost; by using the flawless, high conductive and high transparent graphene material to manufacture the gate, the electronic performance of the thin film transistor can be better; by using the hexagonal boron nitride material to manufacture the gate insulation layer to interact with the gate made by graphene, the electronic performance of the thin film transistor can be promoted; because both the graphene and the hexagonal boron nitride materials are two dimension atomic layer structure material with better bendability and the channel layer uses the flexible organic semiconductor layer, the bendability of the entire thin film transistor can be significantly promoted, which is beneficial for the application of the organic thin film transistor in the flexible display panel.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

For better explaining the technical solution and the effect of the present invention, the present invention will be further described in detail with the accompanying drawings and the specific embodiments.

In drawings,

FIG. 1 is a flowchart of a manufacture method of a flexible vertical channel organic thin film transistor according to the present invention;

FIG. 2 is a diagram of step 1 of a manufacture method of a flexible vertical channel organic thin film transistor according to the present invention;

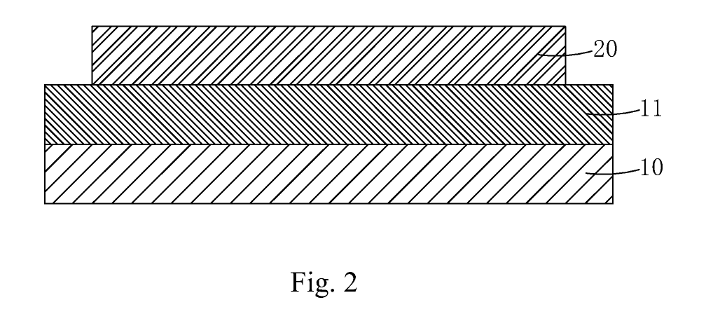

FIG. 3 is a diagram of step 2 of a manufacture method of a flexible vertical channel organic thin film transistor according to the present invention;

FIG. 4A is a diagram of the first embodiment of step 3 of a manufacture method of a flexible vertical channel organic thin film transistor according to the present invention;

FIG. 4B is a diagram of the second embodiment of step 3 of a manufacture method of a flexible vertical channel organic thin film transistor according to the present invention;

FIG. 5A is a diagram of the first embodiment of step 4 of a manufacture method of a flexible vertical channel organic thin film transistor according to the present invention;

FIG. 5B is a diagram of the second embodiment of step 4 of a manufacture method of a flexible vertical channel organic thin film transistor according to the present invention;

FIG. 6 is a lateral view diagram of the first embodiment of a flexible vertical channel organic thin film transistor according to the present invention;

FIG. 7 is a lateral view diagram that the flexible vertical channel organic thin film transistor shown in FIG. 6 is bent;

FIG. 8 is a stereo diagram of the flexible vertical channel organic thin film transistor shown in FIG. 6;

FIG. 9 is a stereo diagram that the flexible vertical channel organic thin film transistor shown in FIG. 6 is bent;

FIG. 10 is a lateral view diagram of the second embodiment of a flexible vertical channel organic thin film transistor according to the present invention;

FIG. 11 is an atomic structure diagram of graphene used in a flexible vertical channel organic thin film transistor according to the present invention;

FIG. 12 is an atomic structure diagram of hexagonal boron nitride used in a flexible vertical channel organic thin film transistor according to the present invention.

### DETAILED DESCRIPTION OF PREFERRED EMBODIMENTS

For better explaining the technical solution and the effect of the present invention, the present invention will be further described in detail with the specific embodiments.

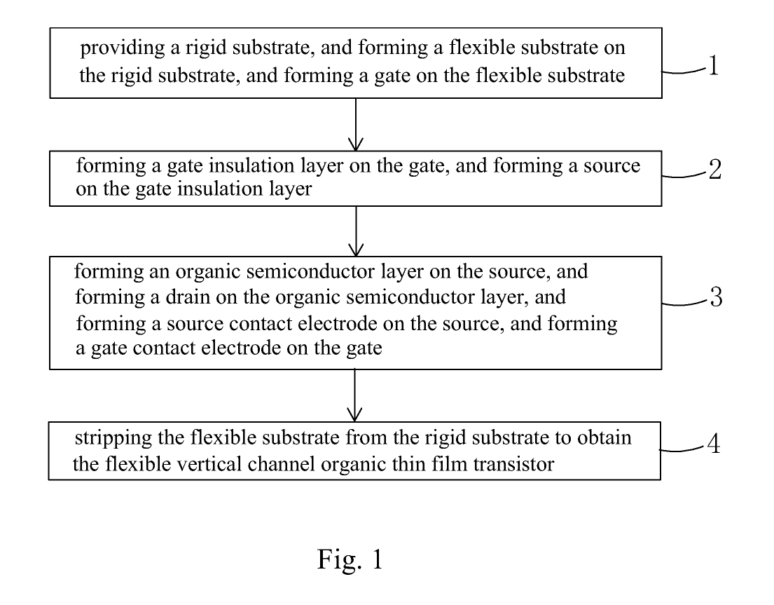

Please refer to FIG. 1. The present invention first provides a manufacture method of a flexible vertical channel organic thin film transistor, comprising steps of:

step 1, as shown in FIG. 1, providing a rigid substrate 10, and forming a flexible substrate 11 on the rigid substrate 10, and forming a gate 20 on the flexible substrate 11.

Specifically, the rigid substrate 10 is a glass substrate.

Preferably, the material of the flexible substrate 11 is a polyimide (PI) thin film.

Specifically, the material of the gate 20 is graphene, and preferably is zero defect graphene.

Specifically, in step 1, the manufacture method of the gate 20 is: employing a method of chemical vapor deposition (CVD) to deposit a graphene layer on the flexible substrate 11, and then patterning the graphene layer to obtain the gate 20.

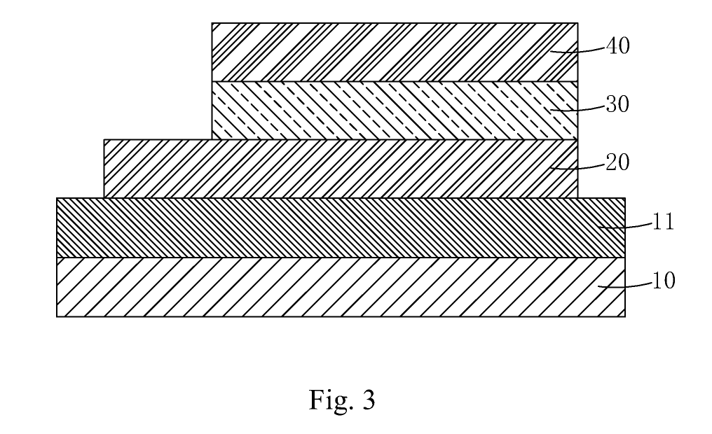

step 2, as shown in FIG. 3, forming a gate insulation layer 30 on the gate 20, and a dimension of the gate insulation layer 30 is smaller than a dimension of the gate 20;

forming a source 40 on the gate insulation layer 30, and a dimension of the source 40 is smaller than or equal to the dimension of the gate insulation layer 30.

Specifically, a material of the gate insulation layer 30 is hexagonal boron nitride (h-BN).

Preferably, the gate insulation layer 30 is two single atomic layers of hexagonal boron nitride thin films.

Specifically, in step 2, the manufacture method of the gate insulation layer 30 is: employing a method of chemical vapor deposition (CVD) to grow the hexagonal boron nitride thin films on the copper foil, and transferring the hexagonal boron nitride thin films grown on the copper foil onto the gate 20 manufactured in step 1, and then, patterning the hexagonal boron nitride thin films to obtain the gate insulation layer 30.

Specifically, a material of the source 40 is carbon nano-tube.

Preferably, the source 40 comprises a plurality of single walled carbon nano-tubes which are sparsely aligned, and the sparse alignment is defined to be the alignment that the plurality of single walled carbon nano-tubes have gaps thereamong. Specifically, the single walled carbon nano-tubes which are sparsely aligned are manufactured with a method of vacuum filtration.

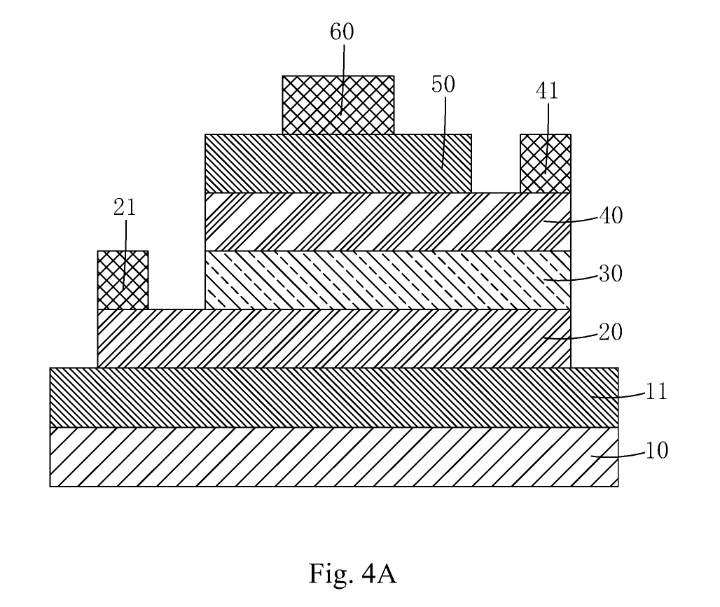

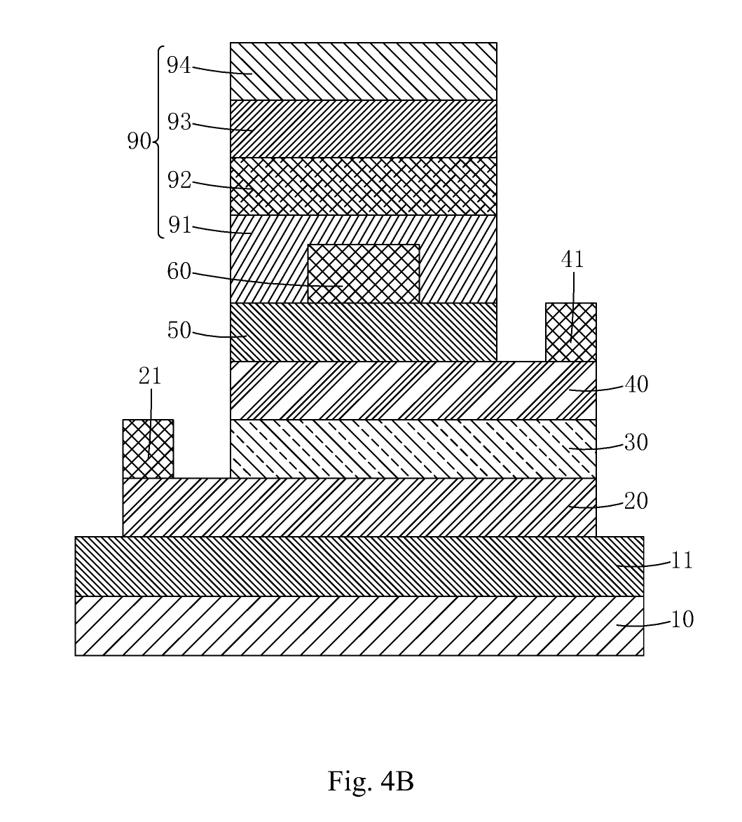

step 3, as shown in FIG. 4A, forming an organic semiconductor layer 50 on the source 40, and a dimension of the organic semiconductor layer 50 is smaller than the dimension of the source 40;

forming a drain 60 on the organic semiconductor layer 50, and a dimension of the drain 60 is smaller than or equal to the dimension of the organic semiconductor layer 50;

forming a source contact electrode 41 which is separately located with the organic semiconductor layer 50 on the source 40;

forming a gate contact electrode 21 which is separately located with the gate insulation layer 30 on the gate 20.

Specifically, in step 3, a method of evaporation is employed to form the organic semiconductor layer 50. Preferably, a material of the organic semiconductor layer 50 is P type (hole) organic semiconductor material.

Specifically, the P type organic semiconductor material comprises one or more alkyl substituted polythiophene, thiophene and derivatives thereof, pentacene, phthalocyanines, perylene and rubrene.

Preferably, in step 3, one mask is employed with an evaporation method to form the drain 60, the source contact electrode 41 and the gate contact electrode 21, and materials of the drain 60, the source contact electrode 41 and the gate contact electrode 21 are the same.

Specifically, the materials of the drain 60, the source contact electrode 41 and the gate contact electrode 21 are metal. Preferably, the materials of the drain 60, the source contact electrode 41 and the gate contact electrode 21 are gold (Au).

Specifically, the gate contact electrode 21 is employed to realize the connection between the gate 20 and the related signal line (such as the scan line). The source contact electrode 41 is employed to be grounded, and thus to realize the grounding of the source 40.

Specifically, a thickness of the organic semiconductor layer 50 is 80 nm-120 nm, and preferably, the thickness of the organic semiconductor layer 50 is 100 nm.

Specifically, in the flexible vertical channel organic thin film transistor manufacture by the present invention, because the source 40 and the drain 60 are respectively located on and under the organic semiconductor layer 50, in which namely, the direction of the channel (the direction from the source 40 to the drain 60) is perpendicular with the horizontal structure layer of the organic semiconductor layer 50. Therefore, the channel length is equal to the thickness of the organic semiconductor layer 50. In comparison with the traditional horizontal channel organic thin film transistor, the channel length of the flexible vertical channel organic thin film transistor manufacture by the present invention is significantly decreased to obtain the larger source drain current under the lower drive voltage.

Furthermore, as shown in FIG. 4B, step 3 further comprises a step of manufacturing an OLED display unit 90 on the organic semiconductor layer 50 and the drain 60, and the OLED display unit 90 comprises a Hole Injection layer 91, an organic light emitting layer 92, an Electron Injection layer 93 and the cathode 94 which are sequentially stacked up on the organic semiconductor layer 50 and the drain 60 from bottom to top, and the drain 60 serves as an OLED anode. By integrating the OLED display unit 90 in the original position on the organic semiconductor layer 50 and the drain 60 and manufacturing the unitary vertical channel organic thin film transistor, it is not required to manufacture the pixel definition layer and the OLED anode on the TFT in comparison with the traditional organic thin film transistor to significantly reduce the manufacture cost of the traditional OLED active matrix and to promote the pixel aperture ratio of the OLED light emitting element.

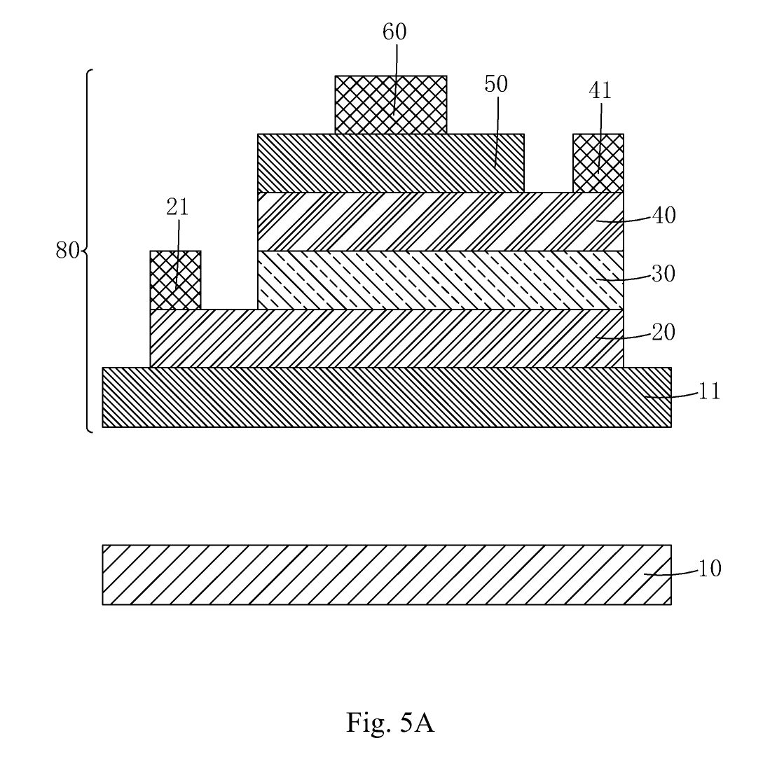

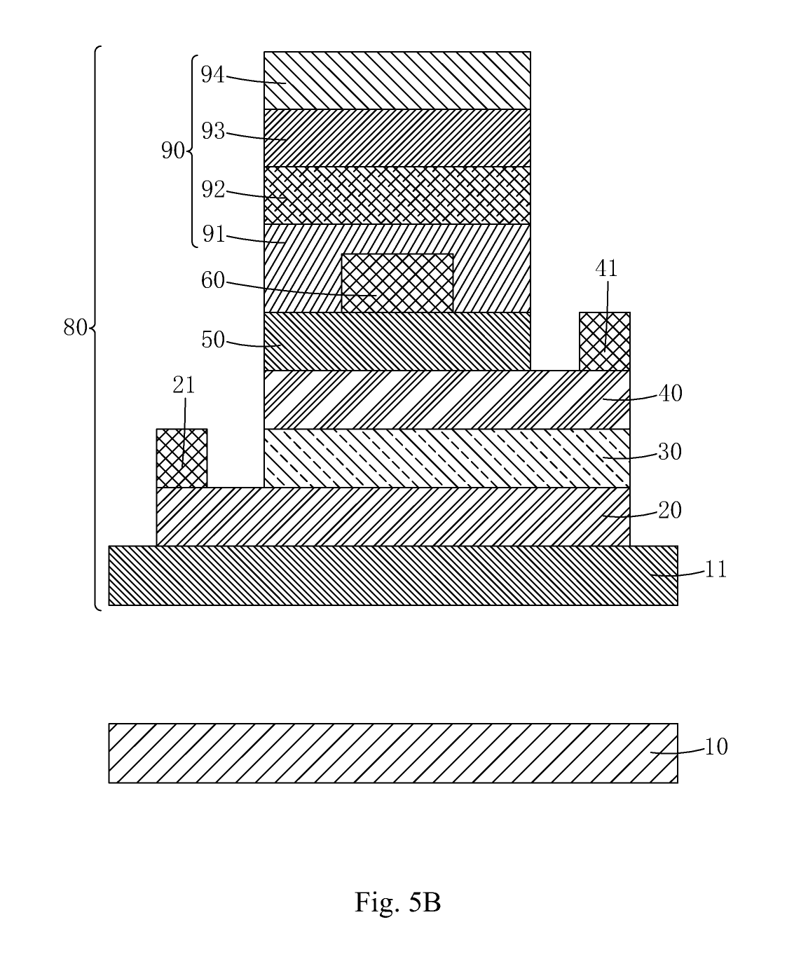

step 4, as shown in FIG. 5A and FIG. 5B, stripping the flexible substrate 11 from the rigid substrate 10 to obtain the flexible vertical channel organic thin film transistor 80.

Specifically, in step 4, the laser lift-off technology is employed to strip the flexible substrate 11 from the rigid substrate 10.

The aforesaid manufacture method of the flexible vertical channel organic thin film transistor, which changes the traditional configuration of the horizontal channel organic thin film transistor and uses the vertical channel configuration to tremendously shorten the channel length so that the thin film transistor can obtain the larger source-drain current under the lower drive voltage, which is beneficial for driving the OLED pixel to emit light under low voltage, the high resolution exposure technology is not required to save the production cost; by using the flawless, high conductive and high transparent graphene material to manufacture the gate 20, the electronic performance of the thin film transistor can be better; by using the hexagonal boron nitride material to manufacture the gate insulation layer 30 and functioning with the graphene gate 20 made by graphene material, the electronic performance of the thin film transistor can be promoted; because both the graphene and the hexagonal boron nitride materials are two dimension atomic layer structure material with better bendability and the channel layer uses the flexible organic semiconductor layer, the bendability of the entire thin film transistor can be significantly promoted, which is beneficial for the application of the organic thin film transistor in the flexible display panel.

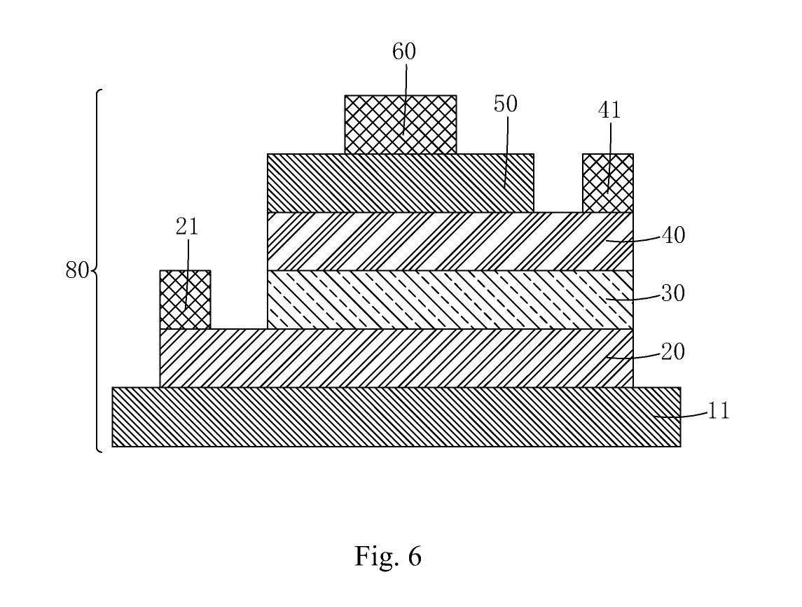

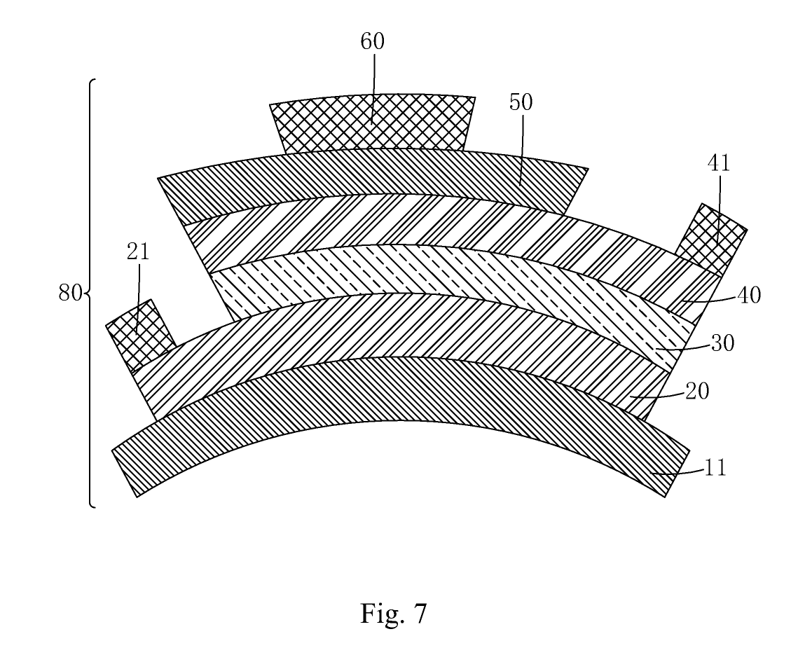

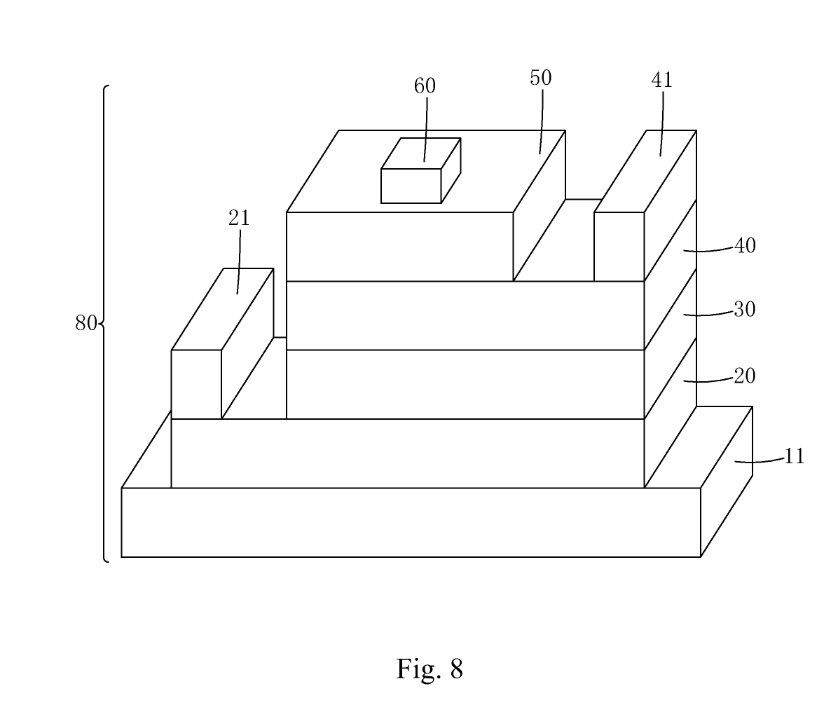

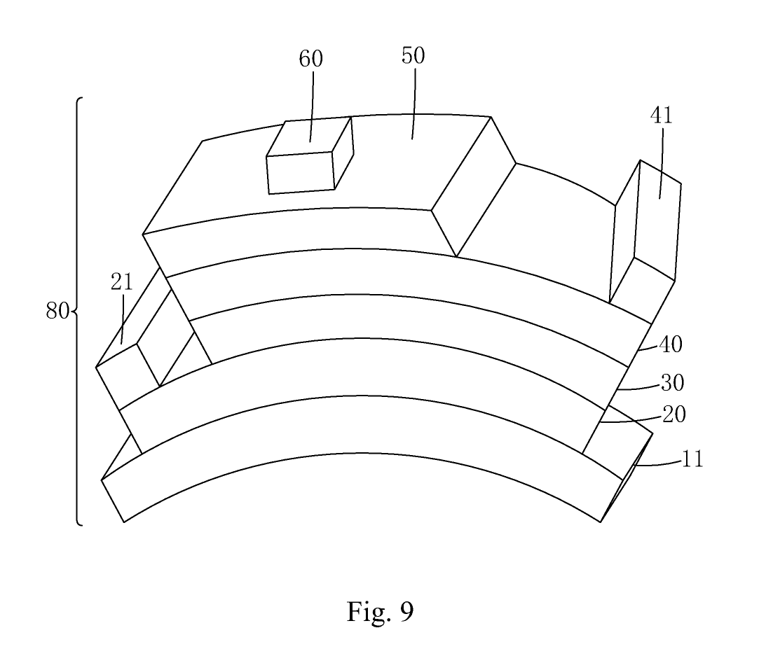

Please refer to FIG. 6 to FIG. 9. On the basis of the aforesaid manufacture method of the flexible vertical channel organic thin film transistor, the present invention further provides a flexible vertical channel organic thin film transistor 80, comprising: a flexible substrate 11, a gate 20 located on the flexible substrate 11, a gate insulation layer 30 and a gate contact electrode 21 which are located on the gate 20 and separately located, a source 40 located on the gate insulation layer 30, an organic semiconductor layer 50 and a source contact electrode 41 which are located on the source 40 and separately located and a drain 60 located on the organic semiconductor layer 50.

Preferably, the material of the flexible substrate 11 is a polyimide (PI) thin film.

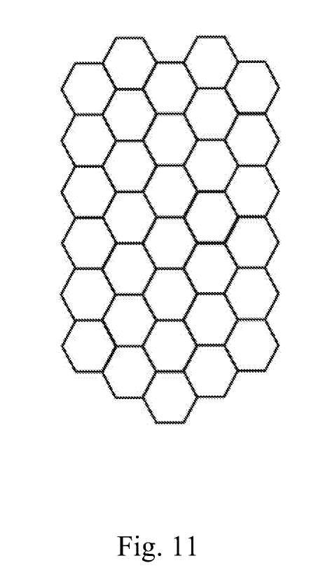

Specifically, the material of the gate 20 is graphene, and preferably is zero defect graphene. Specifically, the atomic structure of the graphene is shown in FIG. 11, which has a very high carrier mobility, conductivity and the transparency, and the elasticity and bendability thereof are truly good, which are beneficial for transport of the electron and the manufacture of the flexible bottom light emitting type OLED display element.

Specifically, a material of the gate insulation layer 30 is hexagonal boron nitride (h-BN). Preferably, the gate insulation layer 30 is two single atomic layers of hexagonal boron nitride thin films.

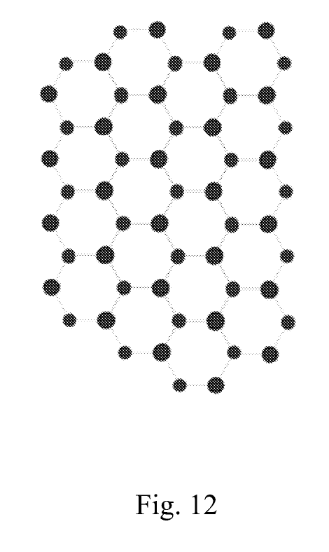

Specifically, the atomic structure of the hexagonal boron nitride is shown in FIG. 12. The insulation layer manufactured by the hexagonal boron nitride has a surface which is very flat and smooth, and the surface defect state density is few, and the dielectric breakdown strength is very high, and it has been proved to be the ideal insulation layer of the graphene base electronic element. The gate 20 manufactured by the graphene material and the gate insulation layer 30 manufactured by the hexagonal boron nitride are used together, and the better electronic performance can be obtained. Because both the graphene and the hexagonal boron nitride are two dimension atomic layer structure materials, in comparison with the organic thin film transistor on the basis of the metal electrode and the inorganic material insulation layer, the organic thin film transistor of the present invention can obtain the better bendability, which can be used for manufacture the flexible OLED display device on the basis of the organic thin film transistor, and can promote the application potential of the organic thin film transistor in the flexible OLED display field.

Specifically, a material of the source 40 is carbon nano-tube, and preferably, the source 40 comprises a plurality of single walled carbon nano-tubes which are sparsely aligned, and the sparse alignment is defined to be the alignment that the plurality of single walled carbon nano-tubes have gaps thereamong. Specifically, the structure of the single walled carbon nano-tubes which are sparsely aligned can act to be conductive on one hand, and on the other hand, the sparse net structure will not completely shield the gate electric field lines.

Preferably, the material of the organic semiconductor layer 50 is P type organic semiconductor material. The P type organic semiconductor material has higher carrier mobility, which can raise the on state current of the organic thin film transistor. Specifically, the P type organic semiconductor material comprises one or more alkyl substituted polythiophene, thiophene and derivatives thereof, pentacene, phthalocyanines, perylene and rubrene.

The drain 60, the source contact electrode 41 and the gate contact electrode 21 are formed in the same evaporation process, and thus materials are the same.

Specifically, the materials of the drain 60, the source contact electrode 41 and the gate contact electrode 21 are metal. Preferably, the materials of the drain 60, the source contact electrode 41 and the gate contact electrode 21 are gold (Au).

Specifically, the gate contact electrode 21 is employed to realize the connection between the gate 20 and the related signal line (such as the scan line). The source contact electrode 41 is employed to be grounded, and thus to realize the grounding of the source 40.

Specifically, the working principle of the flexible vertical channel organic thin film transistor of the present invention is: the schottky contact property is formed between the source 40 manufactured by the carbon nano-tube material and the organic semiconductor layer 50, and in the working process, by regulating the voltage applied on the gate 20 to adjust the schottky barrier between the source 40 and the organic semiconductor layer 50 to realize the objective of controlling the switch performance of the thin film transistor, and it is illustrated that the organic semiconductor layer 50 uses the P type organic semiconductor material:

As applying the negative voltage on the gate 20 (the gate source voltage Vgs<0), because the source 40 comprises a plurality of single walled carbon nano-tubes which are sparsely aligned, these will not completely shield the gate electric field lines, and the gate electric field line can penetrate the source 40 to lower the schottky barrier between the source 40 and the organic semiconductor layer 50 so that the hole amount injected by the source 40 into the organic semiconductor layer 50 increases to form the positive current (on state current/source drain current) flowing from the source 40 to the organic semiconductor layer 50, and the thin film transistor is considered to be in on state. Meanwhile, along with the absolute value of the negative voltage applied on the gate 20 increases, the schottky barrier is more lowered, and the positive current (on state current/source drain current) is larger;

As applying the positive voltage on the gate 20 (the gate source voltage Vgs>0), the gate electric field line still can penetrate the source 40 to increase the schottky barrier between the source 40 and the organic semiconductor layer 50. The holes in the organic semiconductor layer 50 have to cross the barrier which is very high to be injected into the source 40. Therefore, the reverse current flowing from the organic semiconductor layer 50 to the source 40 is extremely small, and the thin film transistor is considered to be the off state.

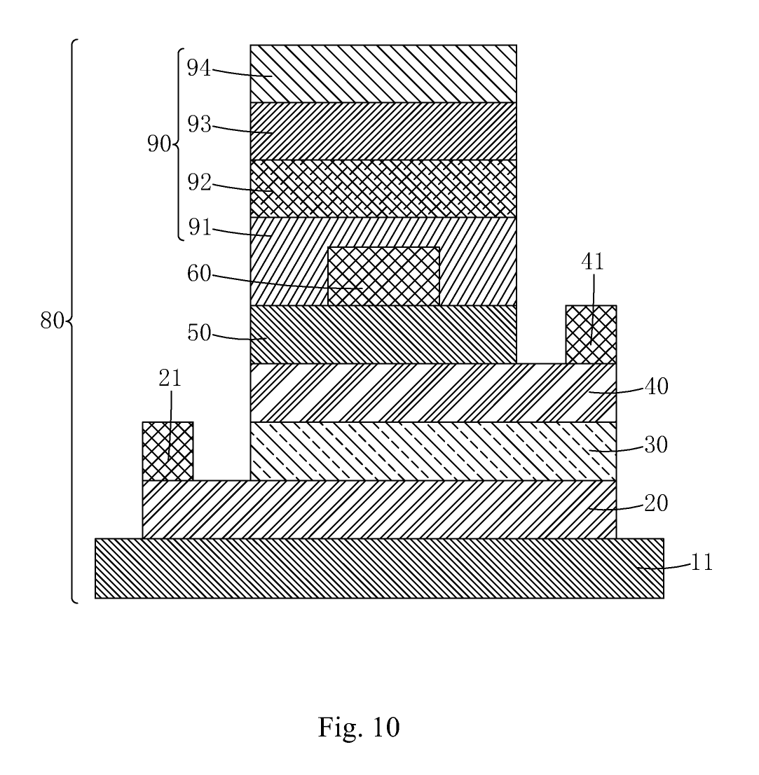

Furthermore, as shown in FIG. 10, the flexible vertical channel organic thin film transistor 80 further comprises an OLED display unit 90 on the organic semiconductor layer 50 and the drain 60, and the OLED display unit 90 comprises a Hole Injection layer 91, an organic light emitting layer 92, an Electron Injection layer 93 and the cathode 94 which are sequentially stacked up on the organic semiconductor layer 50 and the drain 60 from bottom to top, and the drain 60 serves as an OLED anode. By integrating the OLED display unit 90 in the original position on the organic semiconductor layer 50 and the drain 60 and manufacturing the unitary vertical channel organic thin film transistor, it is not required to manufacture the pixel definition layer and the OLED anode on the TFT in comparison with the traditional organic thin film transistor to significantly reduce the manufacture cost of the traditional OLED active matrix and to promote the pixel aperture ratio of the OLED light emitting element.

In the aforesaid flexible vertical channel organic thin film transistor, by using the vertical channel configuration to obtain the higher on state current, it is beneficial for driving the OLED pixel to emit light under lower voltage, and the high resolution exposure technology is not required to save the production cost; the gate 20 manufactured by the graphene material and the gate insulation layer 30 manufactured by the hexagonal boron nitride are used together to ensure the thin film transistor possess the better electronic performance and the bendability and to be beneficial for manufacturing the flexible OLED light emitting element in the original position.

The present invention provides a flexible vertical channel organic thin film transistor and a manufacture method thereof, which change the traditional configuration of the horizontal channel organic thin film transistor and use the vertical channel configuration to tremendously shorten the channel length so that the thin film transistor can obtain the larger source-drain current under the lower drive voltage, which is beneficial for driving the OLED pixel to emit light under low voltage, the high resolution exposure technology is not required to save the production cost; by using the flawless, high conductive and high transparent graphene material to manufacture the gate, the electronic performance of the thin film transistor can be better; by using the hexagonal boron nitride material to manufacture the gate insulation layer to interact with the gate made by graphene, the electronic performance of the thin film transistor can be promoted; because both the graphene and the hexagonal boron nitride materials are two dimension atomic layer structure material with better bendability and the channel layer uses the flexible organic semiconductor layer, the bendability of the entire thin film transistor can be significantly promoted, which is beneficial for the application of the organic thin film transistor in the flexible display panel.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A manufacture method of a flexible vertical channel organic thin film transistor, comprising steps of:
step 1, providing a rigid substrate, and forming a flexible substrate on the rigid substrate, and forming a gate on the flexible substrate;
step 2, forming a gate insulation layer on the gate, and a dimension of the gate insulation layer is smaller than a dimension of the gate;
forming a source on the gate insulation layer, and a dimension of the source is smaller than or equal to the dimension of the gate insulation layer;
step 3, forming an organic semiconductor layer on the source, and a dimension of the organic semiconductor layer is smaller than the dimension of the source;
forming a drain on the organic semiconductor layer, and a dimension of the drain is smaller than or equal to the dimension of the organic semiconductor layer;
forming a source contact electrode which is separately located with the organic semiconductor layer on the source;
forming a gate contact electrode which is separately located with the gate insulation layer on the gate;
step 4, stripping the flexible substrate from the rigid substrate to obtain the flexible vertical channel organic thin film transistor.

2. The manufacture method of the flexible vertical channel organic thin film transistor according to claim 1, wherein a material of the gate is graphene; a material of the gate insulation layer is hexagonal boron nitride.

3. The manufacture method of the flexible vertical channel organic thin film transistor according to claim 1, wherein a material of the source is carbon nano-tube; a material of the organic semiconductor layer is P type organic semiconductor material; a thickness of the organic semiconductor layer is 80 nm-120 nm.

4. The manufacture method of the flexible vertical channel organic thin film transistor according to claim 1, wherein in step 3, one mask is employed with an evaporation method to form the drain, the source contact electrode and the gate contact electrode, and materials of the drain, the source contact electrode and the gate contact electrode are the same; the materials of the drain, the source contact electrode and the gate contact electrode are metal.

5. The manufacture method of the flexible vertical channel organic thin film transistor according to claim 1, wherein step 3 further comprises a step of manufacturing an OLED display unit on the organic semiconductor layer and the drain, and the OLED display unit comprises a Hole Injection layer, an organic light emitting layer, an Electron Injection layer and the cathode which are sequentially stacked up on the organic semiconductor layer and the drain from bottom to top, and the drain serves as an OLED anode.

6. A flexible vertical channel organic thin film transistor, comprising: a flexible substrate, a gate located on the flexible substrate, a gate insulation layer and a gate contact electrode which are located on the gate and separately located, a source located on the gate insulation layer, an organic semiconductor layer and a source contact electrode which are located on the source and separately located and a drain located on the organic semiconductor layer.

7. The flexible vertical channel organic thin film transistor according to claim 6, wherein a material of the gate is graphene; a material of the gate insulation layer is hexagonal boron nitride.

8. The flexible vertical channel organic thin film transistor according to claim 6, wherein a material of the source is carbon nano-tube; a material of the organic semiconductor layer is P type organic semiconductor material; a thickness of the organic semiconductor layer is 80 nm-120 nm.

9. The flexible vertical channel organic thin film transistor according to claim 6, wherein the drain, the source contact electrode and the gate contact electrode are formed in the same evaporation process, and thus materials are the same; the materials of the drain, the source contact electrode and the gate contact electrode are metal.

10. The flexible vertical channel organic thin film transistor according to claim 6, further comprising an OLED display unit located on the organic semiconductor layer and the drain, and the OLED display unit comprises a Hole Injection layer, an organic light emitting layer, an Electron Injection layer and the cathode which are sequentially stacked up on the organic semiconductor layer and the drain from bottom to top, and the drain serves as an OLED anode.

11. A flexible vertical channel organic thin film transistor, comprising: a flexible substrate, a gate located on the flexible substrate, a gate insulation layer and a gate contact electrode which are located on the gate and separately located, a source located on the gate insulation layer, an organic semiconductor layer and a source contact electrode which are located on the source and separately located and a drain located on the organic semiconductor layer;
wherein a material of the gate is graphene; a material of the gate insulation layer is hexagonal boron nitride;
wherein a material of the source is carbon nano-tube; a material of the organic semiconductor layer is P type organic semiconductor material; a thickness of the organic semiconductor layer is 80 nm-120 nm.

12. The flexible vertical channel organic thin film transistor according to claim 11, wherein the drain, the source contact electrode and the gate contact electrode are formed in the same evaporation process, and thus materials are the same; the materials of the drain, the source contact electrode and the gate contact electrode are metal.

13. The flexible vertical channel organic thin film transistor according to claim 11, further comprising an OLED display unit located on the organic semiconductor layer and the drain, and the OLED display unit comprises a Hole Injection layer, an organic light emitting layer, an Electron Injection layer and the cathode which are sequentially stacked up on the organic semiconductor layer and the drain from bottom to top, and the drain serves as an OLED anode.
